(19) United States
(12) Patent Application Publication
(10) Pub. No.: US 2018/0292476 A1
(43) Pub. Date: Oct. 11, 2018

(54) NUCLEAR MAGNETIC RESONANCE MICROPROBE DETECTORS AND METHOD FOR DETECTION OF LOW-VOLUME SAMPLES

(71) Applicant: BATTELLE MEMORIAL INSTITUTE, Richland, WA (US)

(72) Inventors: Mark C. Butler, Richland, WA (US); Ying Chen, Richland, WA (US); Hardeep S. Mehta, Richland, WA (US); Karl T. Mueller, Richland, WA (US); Eric D. Walter, Richland, WA (US)

(73) Assignee: BATTELLE MEMORIAL INSTITUTE, Richland, WA (US)

(21) Appl. No.: 15/483,903

(22) Filed: Apr. 10, 2017

(51) Int. Cl. G01R 33/30; G01R 33/46

(52) U.S. Cl. CPC G01R 33/302; G01R 33/4616

(57) ABSTRACT

NMR microprobe detectors and methodologies that provide enhanced signal sensitivity for low-volume sample detection and analysis are described. In one embodiment the microprobe detector is a flat wire detector with a strip conductor having a length and width and ratio greater than 5 with a substantially uniform surface positioned on a low loss substrate in contact with a sample holder having a generally thin wall or at least a thin portion near where the sample probing and analysis occur.

### STATEMENT REGARDING RIGHTS TO INVENTION MADE UNDER FEDERALLY-SPONSORED RESEARCH AND DEVELOPMENT

This invention was made with Government support under Contract DE-AC05-76RL01830 awarded by the U.S. Department of Energy. The Government has certain rights in the invention.

### FIELD OF THE INVENTION

The present invention relates generally to Nuclear Magnetic Resonance (NMR) spectroscopy and more particularly to NMR microprobe detectors and methods for detection of low-volume samples.

### BACKGROUND OF THE INVENTION

Nuclear magnetic resonance (NMR) spectroscopy is an important analysis tool for characterizing chemical and biological materials including identifying chemical composition, determining molecular structure, measuring transport properties such as diffusion and flow, and conducting in-vitro and in-vivo imaging. However, a longstanding problem with low-volume NMR spectroscopic systems and approaches in the prior art is their generally low detection sensitivity compared with other spectroscopic systems such as mass spectroscopy. Previous attempts to improve sensitivity have centered in reducing size and shape of radio frequency (RF) coils utilized in these systems to more closely match low sample volumes to enhance signal intensity during sample detection. Yet, despite decades of effort to miniaturize these coils, commercial NMR microprobe detectors generally still require typical sample volumes greater than 5 μL (5 mm³) for sufficient detection sensitivity. Most prior art NMR microprobe systems also average spectroscopic signals over a volume of many microliters which limits their ability to be utilized in spectroscopic studies of extremely small samples such as those containing single cells where microscale inhomogeneity is significant. Accordingly new NMR microprobe detectors are needed that improve detection sensitivity in low-volume samples. The present invention is step toward addressing these needs.

The purpose of the foregoing abstract is to enable the United States Patent and Trademark Office and the public generally, especially the scientists, engineers, and practitioners in the art who are not familiar with patent or legal terms or phraseology, to quickly determine the nature and essence of the technical disclosure of the application. The abstract is neither intended to define the invention of the application which is measured by the claims nor is it intended to be limiting as to the scope of the invention in any way.

### SUMMARY

The present invention lies in improved devices and methodologies for performing NMR analyses on low-volume samples using NMR microprobe detectors. In one example the invention lies in the formulation of a NMR microprobe detector for detection of low-volume samples made up of a detector, preferably a flat wire detector having a low loss substrate with a strip conductor having a substantially uniform surface in contact with a sample holder, the sample holder having a generally thin wall or at least a thin portion near where the sample probing is to take place. In some embodiments the strip conductor is a flat wire strip conductor. In some applications the sample holder is held in place on tapered metal contact pads attached to the low loss substrate. These tapered contact pads can be dimensioned to define strip conductor taper angles greater than 30 degrees. In some embodiments the strip conductor has a length to width ratio greater than 5. In some embodiments these arrangements are one sided. Sample holders can involve a variety of structures including a thin walled microcapillary. In some applications, including lab-on-a-chip types of set ups, these sample holder devices may be a microfluidic sample holder configured for fluid connection with a sample volume delivery device that flows low-volume sample into the microfluidic sample holder. The sample holder regardless of shape has a wall with a thickness of preferably less than 50 microns. In some applications an insulting layer is placed between in contact with the copper contact pads and a ground plane. Preferably a close arrangement is provided whereby the distance between a bottom surface of the ground plane and the top surface of the substrate is less than 150 microns.

In one use case a method of detecting a low-volume sample by NMR is disclosed wherein a set-up as described above is placed within a magnetic field and probed using a pulse sequence to generate a detection signal. That detection signal is then captured and identified. This methodology has proven effective particularly when the low-volume sample is disposed at the center of the strip conductor. Sample volumes less than five microliters and even smaller than five nanoliters and even below one nanoliter such as a small sample of a single biological cell have been successfully detected at a sufficient sensitivity. The present methodology is applicable in inhomogeneous materials and in samples that are placed in a carrier fluid. In addition the present invention can be utilized in an inhomogeneous field. Other embodiments of the invention may use other sampling and probing techniques including modified SHARP pulse sequences and zero quantum pulse sequences to generate signals for samples in inhomogeneous magnetic fields, and pulsed spin-locking pulse sequences to increase signal intensity, and various combinations of these pulse sequences and others.

### BRIEF DESCRIPTION OF THE DRAWINGS

FIGS. 1A-1B show different views of components of one embodiment of the present invention.

FIGS. 2A-2B show different sample holder alignments utilized for analysis of low-volume samples in accordance with the present invention.

FIGS. 3A-3B show another embodiment of the present invention of a lab-on-a-chip design.

FIGS. 4A-4B show exemplary circuits for embodiments of the present invention.

FIG. 5A shows a zero quantum spectrum for a low-volume alanine sample obtained with the present invention.

FIG. 5B is an exemplary zero quantum pulse sequence utilized to obtain the spectrum of FIG. 5A.

FIG. 6A shows a 2D heteronuclear spectrum for a low-volume lactate sample obtained with the present invention.

FIG. 6B is an exemplary pulse sequence used to obtain the spectrum of FIG. 6A.

FIGS. 7A-7B show ¹H proton spectra for low-volume sucrose samples acquired with the present invention utilizing different sample alignments.

FIGS. 8A-8C show different 2D spectra obtained from analysis of sucrose with the present invention.

### DETAILED DESCRIPTION

A new NMR microstrip probe and detector for detection and analysis of low-volume samples and a process of making are described hereafter. These embodiments addresses various problems and shortcomings of prior art NMR microprobe systems and approaches. In the following description, embodiments of the present invention are shown and described by way of illustration of contemplated and actual embodiments for carrying out the invention. It will be clear from the following description that the invention is susceptible of various modifications and alternative constructions. The present invention covers all modifications, alternative constructions, and equivalents falling within the spirit and scope of the invention as defined in the claims. Therefore the description should be seen as illustrative and not limiting.

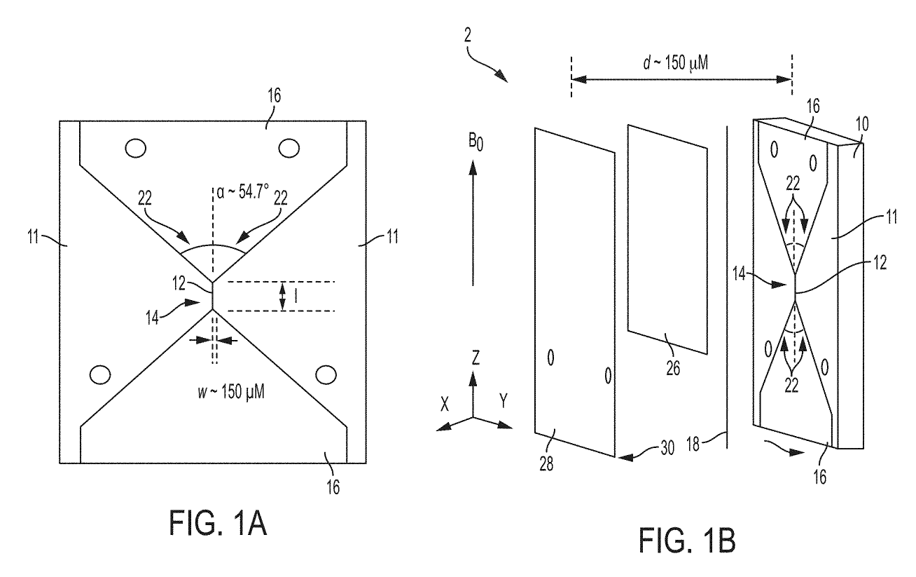

FIGS. 1-8 show a variety of embodiments of the present invention. Beginning first with FIG. 1A an embodiment of a NMR microprobe detector 2 of the present invention is shown having a low loss substrate 10, a strip conductor 12 having a length and a width and a length-to-width ratio greater than 5 and a substantially uniform surface 14 in contact with a sample holder 18 such as a microcapillary. In some embodiments the sample holder 18 is held in place on tapered contact pads 16. Preferably, the sample holder 18 has a wall 20 with a thickness of less than 50 microns. In use the arrangement is designed to hold a sample in the sample holder 18 at a desired location on the strip conductor 12 for analysis. Tapered contact pads 16 define taper angles 22 of various angle dimensions positioned at ends of the tapered contact pads 16 where coupling to the strip conductor 12 occurs. In some embodiments taper angles 22 have an angle dimension at or below 45 degrees such as, for example, 30 degrees. In some embodiments taper angles 22 have an angle dimension that is above 45 degrees such as, for example 54.7 degrees.

In some embodiments such as the embodiment shown in FIG. 1B, the tapered contact pads 16 are connected to or in contact with an insulator 26 made preferably of a flexible and electrically insulating material with a substantially uniform thickness. Other shapes and assemblies with the insulating material are envisioned. The insulator 26 is in contact with to a ground plane 28 with the sample holder 18 in contact with to the strip conductor 12. Preferably a close arrangement is provided whereby the distance between a bottom surface of the ground plane 30 and the top surface of the substrate 11 is less than 150 microns. In this arrangement when the sample capillary was aligned along the length of the strip conductor a resolution line width of 1.5 Hz was obtained. When the sample capillary was positioned orthogonal to the strip conductor a resolution line width of 0.8 Hz was obtained.

Various configurations, materials and examples of these various components have been constructed and tested. In one set of experiments utilizing the microprobe detector without a ground plane, cylindrical microcapillaries with OD of 70 μm and ID of 50 μm or rectangular microcapillaries with dimensions 100 μm×20 μm, a wall thickness of 10 μm, a sample volume of 1 nL and a sample length of 0.2 mm (0.5 mm with sample end plugs) were positioned at the center of the microcapillary attached to the strip conductor; or with a sample length equal to the length of the strip conductor. In tests with rectangular microcapillaries with samples positioned at the center of the microcapillaries, sensitivity of the detector [calculated as a ratio of signal amplitudes following an 810 degree pulse (A810) and a 90 degree pulse (A90), or (A810/A90)] ranged from a low of about 310 at a strip length above zero (˜0.1 mm) rising rapidly to a maximum sensitivity of about 400 at a strip conductor length of about 1 mm and decreasing gradually thereafter as a function of increasing strip conductor length reaching a sensitivity of about 380 at a strip conductor length of 7 mm.

In tests with rectangular microcapillaries containing sample lengths equal to the microcapillary length a maximum sensitivity of about 385 was observed at a strip conductor length of about 1 mm converging thereafter and matching sensitivities for centered samples. In corresponding tests with cylindrical capillaries maxima for centered samples and full length samples were about 355 and 350, respectively at a strip length of about 1 mm converging again with decreasing sensitivities as a function of increasing strip length down to about 340 at a strip length of 7 mm.

In tests with a ground plane positioned 150 μm from the strip conductor with rectangular microcapillaries containing short length and centered samples, sensitivity of the detector (A810/A90) ranged from a low of about 660 at a strip length above zero (˜0.1 mm) reaching rapidly rising to a maximum sensitivity of about 690 at a strip length of about ˜0.8 mm decreasing thereafter to a sensitivity of about 640 at a strip length of 3 mm to about 570 at a strip length of 5 mm and to about 520 at a strip length of 7 mm. Sensitivities for rectangular microcapillaries with a full sample length exhibited a maximum sensitivity of about 675 at a strip length of ˜0.8 mm converging thereafter with previous sensitivity values. In corresponding tests with cylindrical capillaries, maxima for centered samples (0.2 mm sample length) and full capillary length samples were about 650 and 640, respectively at a strip length of about of ˜0.8 mm, again with like converging and decreasing sensitivities with increasing strip length. These results show rectangular capillaries have a generally higher sensitivity that can be selected when sensitivity is a primary consideration. Cylindrical capillaries have a generally higher RF homogeneity that can be selected when RF homogeneity is a primary consideration such as in 2D spectroscopic applications. Close magnetic susceptibility matches between the substrate (e.g., glass microfiber reinforced PTFE composites) and Teflon tape (χ_PTFE=−10.5×10⁻⁶) and copper strip conductor (χ_copper=−9.63×10⁻⁶) can be expected to enhance resolution when optimized.

In another set of tests, a cylindrical microcapillary containing 1 nL of DI water positioned at the center of the microcapillary was attached at the center of the strip conductor and aligned along the length of the strip. A resolution of 1.5 Hz was obtained. In a separate test, the microcapillary was positioned orthogonal (transverse) to the length dimension of the strip conductor. A resolution of 0.8 Hz was obtained. In other tests maximum sensitivity was obtained at a ratio (1/w) of strip length (l) to strip width (w) of from about 5 to about 10 and with suitable RF homogeneity. In general these experiments show microprobe detectors of the present invention demonstrate a high detection sensitivity, a high RF homogeneity (A810°/A90° from about 70% to about 80%), and high resolution (0.8-1.5 Hz) suitable for 1D and 2D NMR spectroscopy on low-volume samples including samples with sub-nanoliter volumes. Results further demonstrate that RF homogeneity, detection resolution, and detection sensitivity can be simultaneously improved by adding a ground plane to the detector; and optimizing (e.g., utilizing numerical simulations) microstrip dimensions and sample positioning.

Sub-nanoliter samples were introduced at the center of a microcapillary attached to the strip conductor with ends in contact with the tapered contact pads. Samples were delivered to the center (0.2 mm sample length) within the microcapillary between two fluorinert FC-43 end plugs leaving an air filled gap on either side of the centered sample at least 2 mm away from the edge of the microcapillary endplugs from a 10 μL Hamilton syringe coupled to a syringe pump running at a rate of 1 μL/hr until the desired volume was delivered. Magnetic susceptibility of the Fluorinert (FC-43) plugs was close to that of the copper strip conductor and copper contact pads (χ_FC-43=−8.23×10⁻⁶ is close to χ_copper=−9.63×10⁻⁶ compared to χ_air=3.6×10⁻⁷). Ends of the microcapillary were sealed with beeswax at 140° C. after sample injection. Sample positioning was observed under an optical microscope. These tests demonstrated that low-volume NMR microprobe detectors of the present invention can be incorporated with lab-on-chip systems that include delivery components and utilize sample volumes smaller than what microprobe NMR detector systems in the prior art provide.

In one set of tests one embodiment of the microprobe detector with a surface finish comprised of rolled copper foil was utilized. Microcapillaries comprised of various materials and dimensions including fused silica (cylindrical ID 50 μm/OD 80 μm), quartz (cylindrical ID 80 μm/OD 100 μm), polycarbonate (cylindrical ID 80 μm/OD 100 μm) and borosilicate (rectangular 100 μm×50 μm) and various sample materials including, for example, pure DI H2O, ethanol, and methanol were utilized. Spectra were collected utilizing both gradient echo and spin echo locking pulse sequences. With the microcapillary aligned along the length dimension of the strip conductor, single-scan 1H spectra of H2O showed a dramatic decrease in linewidth from a few hundred Hz down to ˜2.5 Hz. Linewidths remained at ˜2.5 Hz at sample lengths from about 0.5 mm down to about 0.15 mm. In one test, an increased linewidth to ˜7 Hz resulted when sample length was reduced to 0.1 mm. These results demonstrate that sample lengths less than the full microcapillary length generally resulted in better resolution due to a reduced B₀ inhomogeneity. This approach also allows contact pad 16 taper angles 22 above 45 degrees to be utilized further enhancing detector sensitivity compared with prior art microprobe detectors.

One embodiment of the microprobe detector with a ground plane and a thin (˜71 μm) insulator of Teflon tape was also tested. Separation distance between the strip conductor and ground plane was 150 um. A 0.5 mm (0.98 nL) sample was encapsulated within a microcapillary by two FC-43 plugs. Microcapillary was attached at the center of the strip conductor to minimize inhomogeneous signal contributions from the tapered ends of the contact pads with their respective taper angles. Results showed a significant increase in sensitivity (A810°/A90° to 0.75. The 90° pulse duration reduced to 2.81 μs representing an RF strength of 88.9 kHz at 0.25 W. RF conversion efficiency was 4.18 mT/(W)^{1/2} representing a 20 fold increase in RF efficiency compared to a commercial (Bruker Biospin MRI GmbH) 5 mm probe (0.21 mT/(W)^{1/2} obtained from a 90° pulse width of 20 μs at 2 W) utilizing the same spectrometer. In addition to these specific examples a variety of other materials may be utilized in the described arrangement. Overall, testing demonstrated that these embodiments and configurations enable analysis of sub-nanoliter liquid samples at good RF homogeneity and enhanced sensitivity.

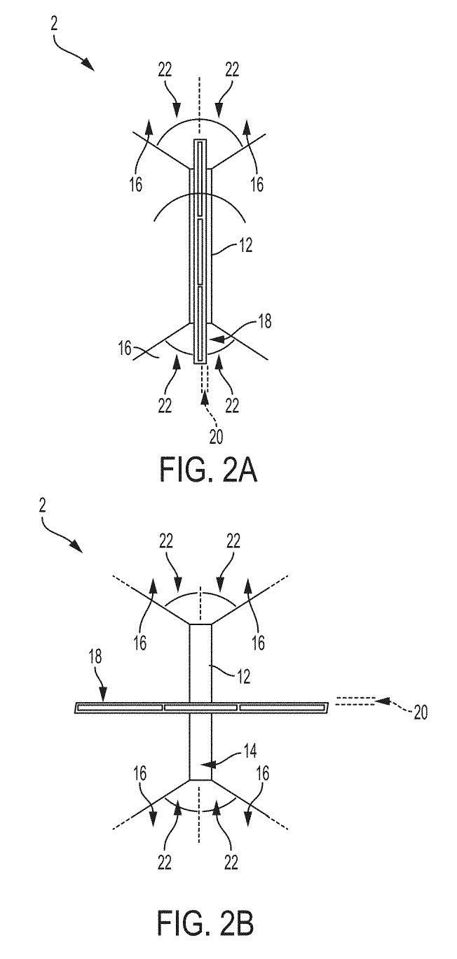

FIGS. 2A-2B show two exemplary alignment configurations for the microfluidic sample holder 18 during low-volume sample analysis in accordance with the present invention. In preferred embodiments, the sample holder 18 is a microcapillary tube that includes a wall 20 with a thickness of ˜50 um. In other applications the microcapillary is rectangular. Other microcapillary shapes are also envisioned. In some applications as shown in FIG. 2A the microcapillary 18 is positioned so as to be aligned along the length dimension of the strip conductor 12. In other applications such as the one shown in FIG. 2B, the microcapillary 18 is positioned orthogonal to the length dimension of the strip conductor 12. The sample holder 18 may extend from one end of the contact pad 16 to the other end of the other contact pad 16 along the length dimension of the strip conductor 12. In other applications the sample holder 18 may be positioned on the strip conductor 12 between contact pad 16 taper angles 22 so as to match the length dimension of the strip conductor 12.

In use a sample is loaded into the sample holder 18 and placed in a desired location on the strip conductor 12. In some embodiments the sample holder 18 may be held in place in contact with the tapered contact pads 6. The NMR device is then operated and the sample is probed in a magnetic field and the generated detection signals are returned to the detector in the instrument. The close positioning of the sample materials to the strip conductor 12 enables sensitive detection of low-volume and extremely low-volume samples which were not possible in prior art microprobe detectors. Taper angles enhance the recognition of the generated signal and enhance detection of the generated signal over competing signals and fields. This coupled with variable pulse sequencing enables detection of very low sample volumes and inhomogenous samples which the prior art devices are unable to accomplish. Improved resolution can also be had by matching magnetic susceptibilities of components (e.g., within ±10%) including, for example, the low loss substrate 10, insulator 26, ground plane 28, and carrying fluid (not shown). Microfabricated chips and chip components attached to, or directly fabricated on, the strip conductor 12 can be replaced or exchanged as a single replaceable module.

The microprobe of the present invention can deliver various pulse sequences described hereafter which optimize detection of a high frequency signal after one or more periods of spectroscopic evolution during which pulses are applied. In some applications the microprobe utilizes pulse sequences adapted to acquire high-resolution spectra in an inhomogeneous field preserving spectroscopic resolution for sensitive detection of low-volume samples such as spectroscopy of single cells. Microprobes of the present invention can also utilize dynamic nuclear polarization (DNP) to further enhance resulting detection sensitivity (SNR) of the microprobe detector.

In some applications pulse sequences utilize coherence-transfer echoes, for example, during one or more periods of spectroscopic evolution during which the pulses are applied to eliminate line broadening and spin echoes during the detection period. These pulse sequences optimize detection of the high-frequency detection signal by collapsing the detection signal into a narrow bandwidth during the detection period increasing energy in the signal and providing optimal sensitivity which yields high resolution spectra even in the presence of field inhomogeneities. By relaxing need for near perfect homogeneity, samples can be placed in close proximity to the strip conductor of the microprobe detector below 50 μm, more particularly down to 30 μm or less, and most particularly down to 10 μm or less decreasing separation distance between the sample and detector by at least an order of magnitude compared to prior art low-volume microprobes.

In other embodiments modified SHARP pulse sequences and zero quantum (ZQ) pulse sequences that incorporate pulsed spin locking are utilized to provide sensitive (i.e., >SNR signal) detection and high-resolution spectra including, for example, 2-D homonuclear and 2-D heteronuclear COSY and TOCSY spectra suitable for two dimensional spectroscopy of these low (e.g., sub-nanoliter) volume samples. In addition fast spin-echo imaging may be utilized enabling high-throughput metabolic studies.

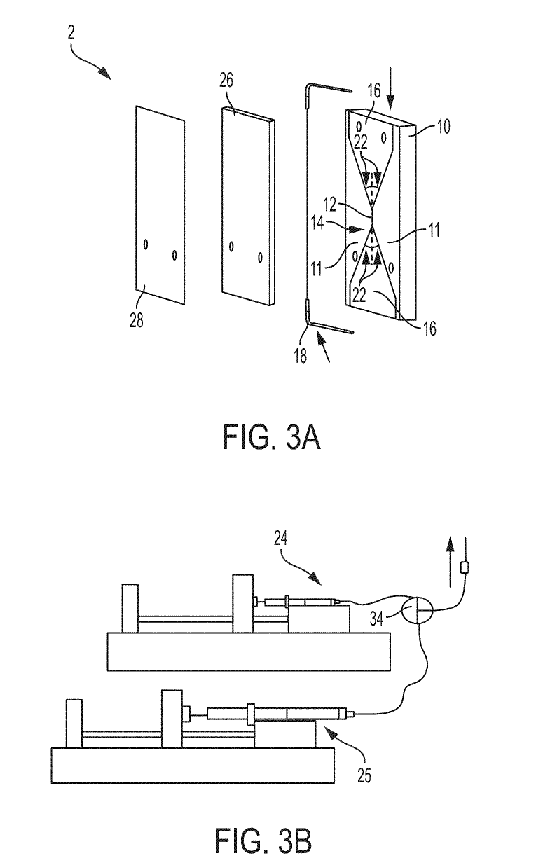

FIGS. 3A-3B show other embodiments of the NMR microprobe detector 2 for use in lab-on-chip systems and applications. In this embodiment the microprobe detector 2 is formed on a low loss microfluidic chip substrate 10 with the tapered contact pads 16 and microfluidic sample holder 18 positioned similar to the descriptions in FIGS. 1A and 1B. In some applications the sample holder 18 is a microfluidic sample holder that is operatively coupled to a sample fluid delivery device 24 and a carrier fluid delivery device 26 that individually or collectively deliver metered microfluidic volumes or amounts of sample (e.g., picoliter volumes) through a loading or mixing valve 38 and into the microfluidic sample holder 18. (See FIG. 3B). In some applications the operation of these pumps and valves that facilitate sample loading can be automated and controlled by devices such as syringe pumps and pneumatic or mechanical valves. These examples are not intended to be limiting. In this example an insulator 26 provides separation between the ground plane 28 and the substrate 10.

In use positioning microfluidic droplets containing low-volume samples at the center within the microfluidic sample holder 18 can be monitored in real time utilizing a suitable monitoring method such as MRI imaging utilizing, for example, fast spin-echo imaging.

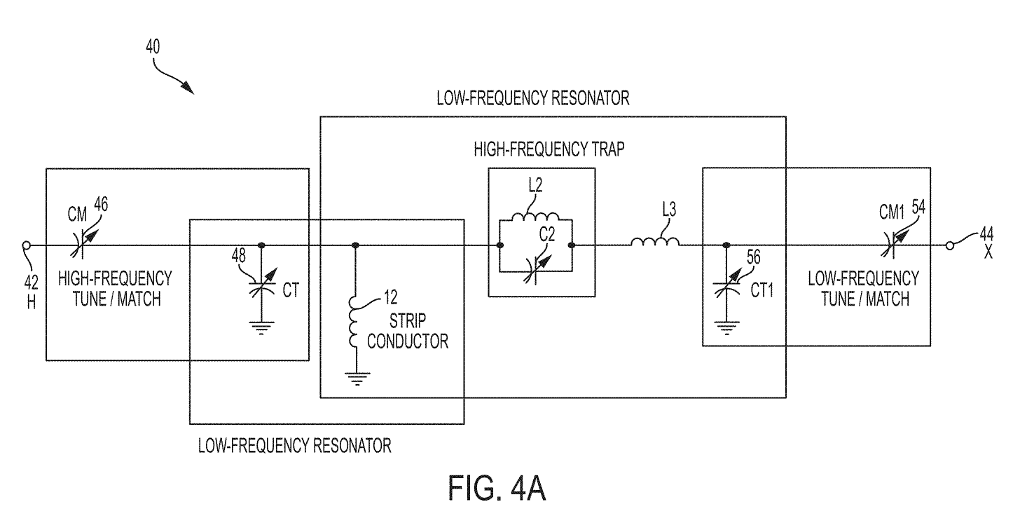

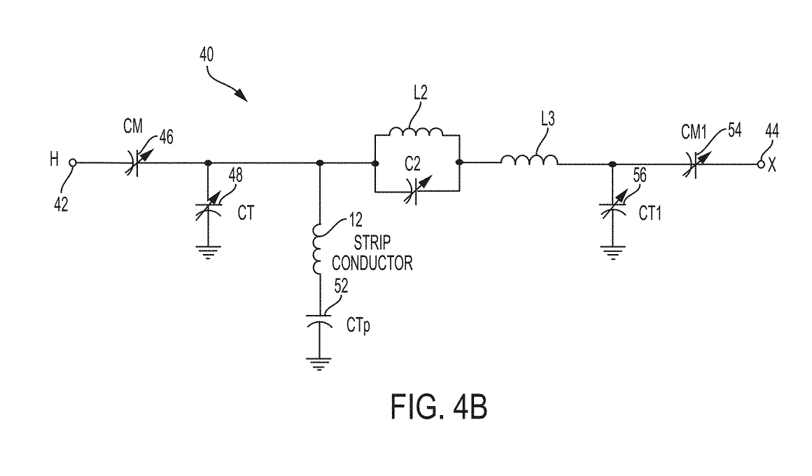

FIGS. 4A and 4B show exemplary embodiments of double resonance circuits tuned for high frequency detection for high detection analysis of low-volume samples. FIG. 4A shows one embodiment of a dual channel probe circuit 40 with a configuration modified and tuned for detection of low-volume liquid samples. The circuit 40 includes a high frequency (HF) channel 42 and a low frequency (LF) channel 44 that provides optimal sensitivity in the high frequency channel while allowing RF pulses to be applied in both channels. In this embodiment, one end of the strip conductor 12 is grounded. This probe circuit overcomes limitations of two channel circuits known in the prior art that deliver generally reduced and average sensitivities split or shared equally between the HF channel and the LF channel which sacrifice overall detection sensitivity in the high-frequency channel to allow detection in both the HF and LF channels. In the prior art embodiments, the detection signal in the low frequency channel is often too weak for direct detection of low-volume samples. The instant probe circuit does not sacrifice detection sensitivity in the high frequency channel to allow for detection in the low frequency channel as done in the prior art thus retaining detection sensitivity for low-volume samples. FIG. 4B shows another embodiment of a dual channel probe circuit 40 in which both sides of the strip conductor 12 are connected to variable capacitors. Variable capacitors (46 and 48) and (54 and 56) may be utilized for tuning (T) and impedance matching (M) in the high frequency channel 42 and low frequency channel 44, respectively. An additional capacitor (CTp) 52 is shown that can be utilized to enable balanced driving of the strip conductor 12 that improves RF homogeneity.

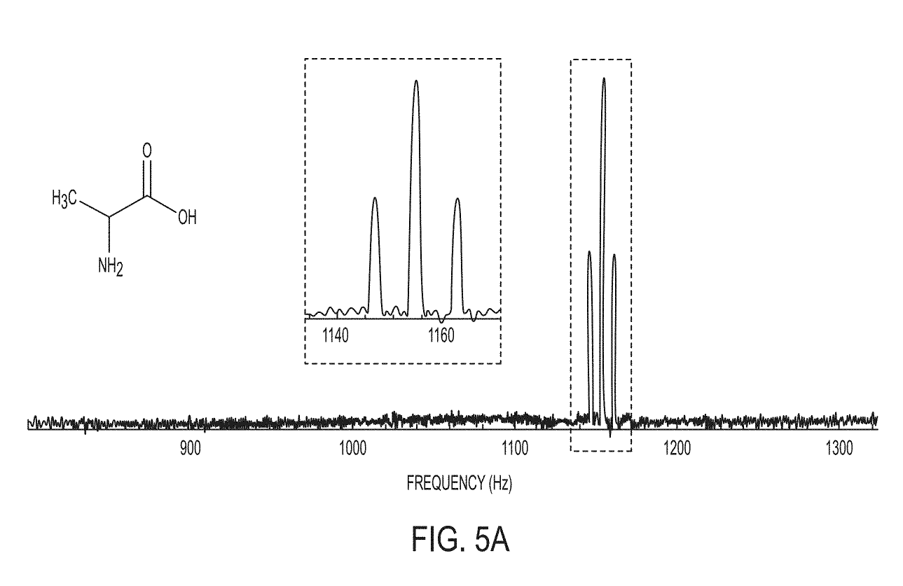

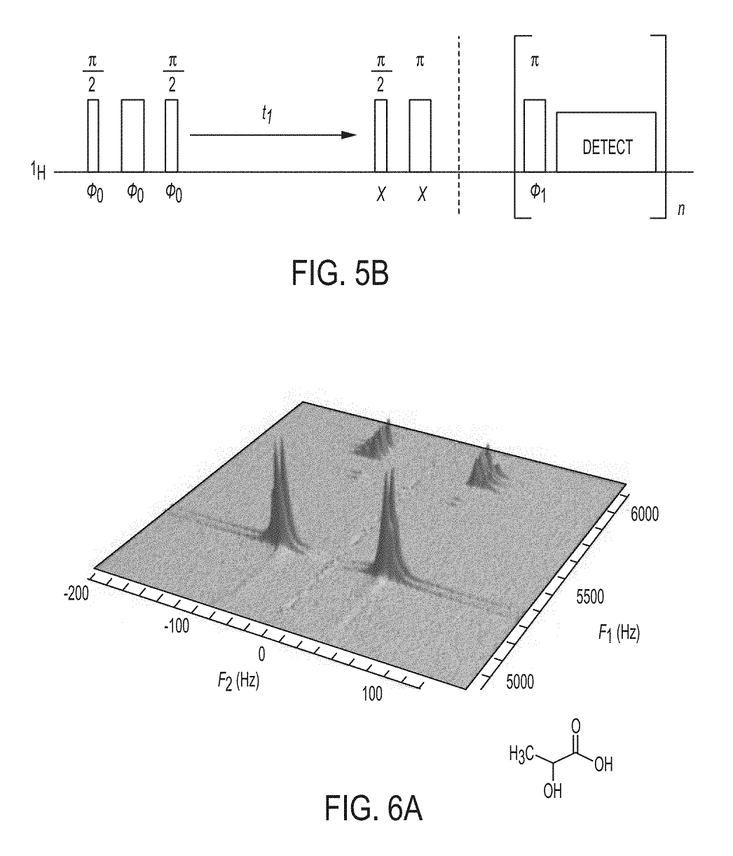

In one set of experiments a NMR microprobe detector with a low loss substrate made of polytetrafluoroethylene (PTFE, e.g., TEFLON®) with a copper ground plane, tapered copper contact pads, and strip conductor were utilized and assembled as shown in FIGS. 1A and 1B. The strip conductor had a strip length (l) of 200 μm with a fixed width (w) of 150 μm. Taper angles (α) of the tapered contact pads were 54.7 degrees. Tapered contact pads and strip conductor were covered with a thin insulator made of a layer (˜71 μm) of Teflon tape. Distance between the bottom surface of the ground plane and the top surface of the substrate was about 150 microns (μm). A sample capillary was then aligned in two different arrangements. In various tests 500 pL low-volume alanine solutions (1M in alanine) prepared in D₂O water were analyzed. Liquid samples were introduced in microcapillaries placed onto the strip conductor. A zero quantum (ZQ) pulse sequence was utilized to probe the sample volume. Number of evolution time (T1) increments was 2048. Experiment time was 20 hours. FIG. 5A shows a representative homonuclear ZQ spectrum obtained for these low-volume alanine samples. The figure shows a triplet due to a ZQ coherence involving two spins involving the CH group and the CH₃ group of the alanine, respectively. FIG. 5B shows the pulse sequence utilized to obtain the spectrum of FIG. 5A with cycled phases, phi (Φₖ), as shown. Evolution of the ZQ coherence occurs during time T1. Detection period begins at the dashed line during which spin locked magnetization is detected between closely spaced pi (π) pulses.

### Example 2

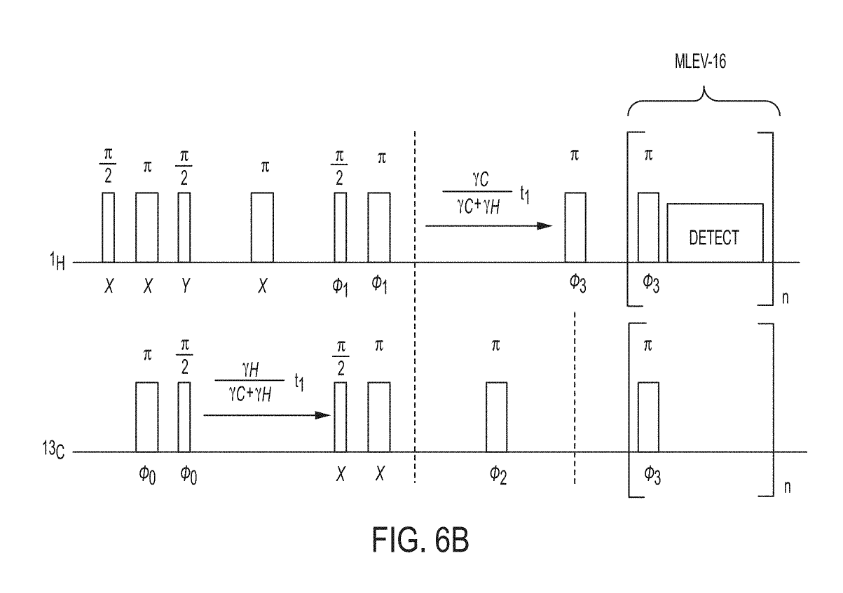

In another set of experiments, liquid samples were taken from a 100 mM lactate solution prepared in water, and processed in a similar set up as described above. 15 nL of lactate sample was introduced within a microcapillary placed onto the strip conductor and analyzed using a modified SHARP pulse sequence with a coherence transfer echo to probe the sample. FIG. 6A shows a representative 2D heteronuclear spectrum obtained for the lactate sample. FIG. 6B shows the modified SHARP pulse sequence utilized to obtain the lactate sample spectrum. The figure shows a triplet due to a ZQ coherence involving two spins involving the CH group and the CH₃ group of the alanine, respectively. FIG. 5B shows the pulse sequence utilized to obtain the spectrum of FIG. 5A with cycled phases, phi (Φₖ), as shown. Evolution of the ZQ coherence occurs during time T1. Detection period begins at the dashed line during which spin locked magnetization is detected between closely spaced pi (π) pulses.

### Example 3

In other experiments embodiments of the strip conductor detector 2 described above were used with and without a ground plane to perform 2D COSY and TOCSY spectroscopy experiments in a NMR microprobe. Liquid sucrose samples with sample volumes ranging from about 0.63 nL to about 1.3 nL and sucrose concentrations ranging from about 0.13 nmol to about 1.3 nmol were utilized. Sample solutions were encapsulated between two fluorinert plugs (260 μm sample length) at the center of thin wall cylindrical microcapillaries attached to the strip conductor.

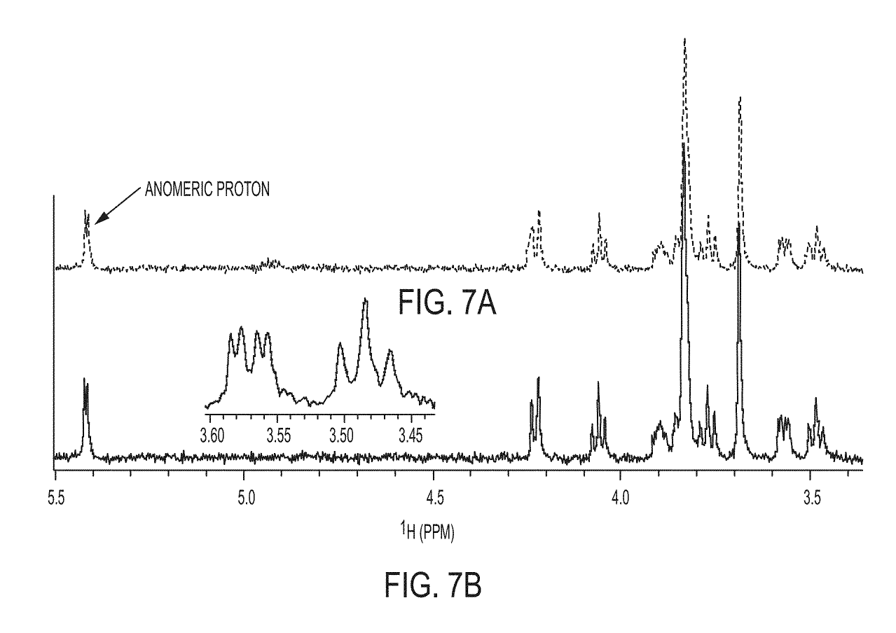

In one set of tests, a 1.3 nL (0.26 nmol) sucrose sample in H₂O (0.2 M in 1.3 nL) centered (0.26 mm sample length) within a thin wall (20 μm) microcapillary (OD 100 μm and ID 80 μm) was attached transverse to the strip conductor. Sample was analyzed without a ground plane. Acquisition parameters included 256 (evolution time T1) increments; 32 scans; an acquisition time of 0.255 seconds; a relaxation delay of 1.5 seconds; and utilizing water suppression by pre-saturating the sample for 1 sec at a pre-saturation power 1 μW (60 dB). Run time of each experiment was 32 minutes for a total experimental time of 4.5 hours. FIG. 7A shows a representative homonuclear ¹H spectrum of this sample. SNR of the anomeric proton was 20. Limit of Detection [calculated as the sample (mole) quantity needed to achieve a SNR of 3 in one second or (nLODₘ)] was 1.21 nmol s^{1/2} in the transverse sample position.

In another set of tests, a 0.63 nL (0.13 nmol) sucrose sample in H₂O (0.2 M in 0.63 nL) centered (0.32 mm sample length) within a thin wall (30 μm) microcapillary (OD 80 μm and ID 50 μm) was attached and aligned along the length of the strip conductor. The sample was analyzed with a ground plane. Acquisition parameters were the same as previous tests with the exception of pre-saturating the sample for 1 sec at a pre-saturation power 0.1 μW (70 dB). Again, run time of each experiment was 32 minutes for a total experimental time of 4.5 hours. FIG. 7B shows a representative homonuclear ¹H spectrum of this sample. SNR of the anomeric proton was 16. Limit of Detection (nLODₘ) was 0.73 nmol s^{1/2} in the aligned position along the length dimension of the strip conductor. These results show transverse sample positioning provides a better resolution generally; parallel positioning provides a better sensitivity generally.

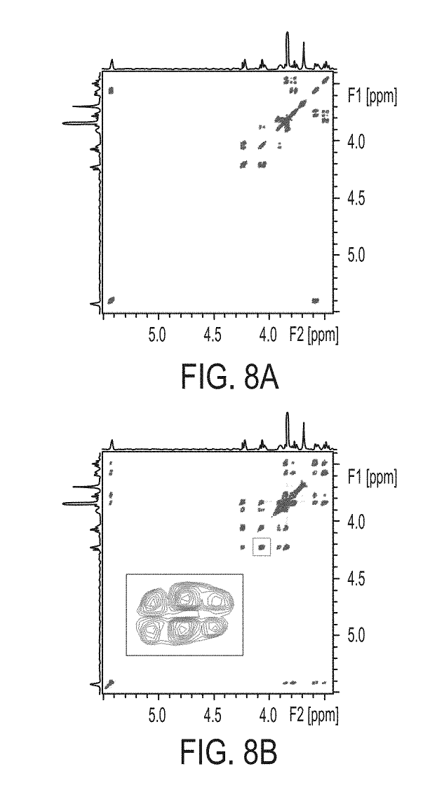

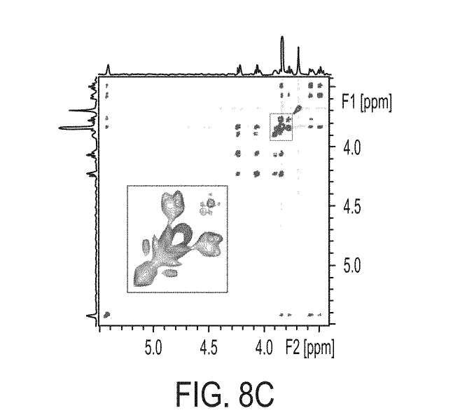

FIGS. 8A-8B show corresponding homonuclear ¹H-¹H 2D COSY (8A) and TOCSY (8B) spectra obtained without and with the ground plane for the samples of FIG. 7A and FIG. 7B, respectively. Experimental run time was 4.5 hours for each sample. FIG. 8C shows a homonuclear TOC SY spectrum obtained with the ground plane for the 0.63 nL (0.13 nmol) sucrose sample. Number of scans was increased to 200 for a total experimental time of 27.5 hours.

At these low volumes, a high sensitivity (nLODₘ=0.73−1.21 nmol s^{1/2}) and a high RF homogeneity (A_{810°}/A_{90°}=70%-80%) were obtained. Sensitivity was 2-3 times greater on average when compared with prior art stripline detectors even at sample volumes of 600 nL. Results demonstrate that microprobe detectors of the present invention enable high performance 2D NMR spectroscopy of sub-nanoliter liquid samples without sample scaling problems found in detectors of the prior art.

Microprobe detectors of the present invention (1) provide high detection sensitivity, a high RF homogeneity, and a high resolution suitable for 1D and 2D NMR spectroscopy of sub-nanoliter samples; (2) are scalable enabling analyses of a wide range of low-volume samples; (3) provide one-sided detection enabling the strip conductor to be placed directly beneath and in close proximity to the low-volume samples for maximum detection sensitivity; (4) are robust to field inhomogeneity; (5) can be integrated into microfabricated devices such as microfluidic chips enabling utilization of NMR in lab-on-chip systems and applications not previously provided by prior art microprobe analysis systems and approaches; and (6) are easily batch fabricated at a relatively low cost.

The NMR microprobe detectors described herein address various unresolved sensitivity problems in the prior art that enhance potential applications and study in such areas as high-throughput metabolomics; drug screening; electrolytes; aerosol particles; chemical composition and identification; structure determination; diffusion and flow transport measurements; and in vitro and in vivo imaging. In addition, the microprobe detector can be utilized for detection and spectroscopy of extremely small samples such as those containing single cells that prior art systems generally cannot provide due to their low sensitivity and generally poor resolution due to low-volume sample inhomogeneity. Thus, the present invention has the potential to address many scientific, medical, and industrial problems stemming from microscale heterogeneity in low-volume sample materials. In addition, the microprobe detector has shown potential in varied microfluidic chip applications including high-throughput metabolic studies such as single cell imaging and localized spectroscopy.

While a number of embodiments of the present invention have been shown and described, it will be apparent to those skilled in the art that many changes and modifications may be made without departing from the invention in its broader aspects. The appended claims are therefore intended to cover all such changes and modifications as fall within the scope of the invention.

What is claimed is:

1. A Nuclear Magnetic Resonance (NMR) microprobe detector comprising:
a low loss substrate defining a strip conductor with a substantially uniform surface on said substrate; and
a pair of tapered contact pads attached to said low loss substrate configured to hold a sample holder containing a sample in contact with said strip conductor surface;
whereby low-volume samples are presented through the sample holder to the strip conductor for analysis.

2. The detector of claim 1 wherein the tapered contact pads define strip conductor taper angles greater than 30 degrees.

3. The detector of claim 1 wherein the strip conductor has a length to width ratio greater than

4. The detector of claim 1 wherein the microfluidic sample holder is a thin walled microcapillary.

5. The detector of claim 4 wherein the sample holder is a microfluidic sample holder configured for fluid connection with a sample volume delivery device that flows a low-volume sample into the microfluidic sample holder.

6. The detector of claim 1 wherein the sample holder has a wall with a thickness of less than 50 microns.

7. The detector of claim 1 further comprising an insulator in contact with the tapered contact pads.

8. The detector of claim 7 further comprising a ground plane in contact with the insulator.

9. The detector of claim 8 wherein the distance between a bottom surface of the ground plane and the top surface of the tapered contact pads is less than 150 microns.

10. The detector of claim 1 wherein the detector is positioned on a chip.

11. A NMR microprobe detector for detection of low-volume samples, comprising:
a flat wire detector having a low loss substrate with a strip conductor having a length and a width and a length-to-width ratio greater than 5 and a substantially uniform surface in contact with a sample holder, the sample holder having a wall with a thickness of less than 50 microns.

12. A method of detecting a low-volume sample by NMR, the method comprising the steps of:
probing a low-volume sample in a sample holder on a strip conductor with a uniform surface in a magnetic field using a pulse sequence to generate a detection signal; and
detecting the detection signal.

13. The method of claim 12 wherein the low-volume sample is less than five nanoliters (5 nL).

14. The method of claim 12 wherein the low-volume sample is disposed at the center of the strip conductor.

15. The method of claim 14 wherein the low-volume sample is less than five microliters (5 μL).

16. The method of claim 12 wherein the low-volume sample includes an inhomogeneous field generating material such as a single biological cell.

17. The method of claim 12 wherein the low-volume sample comprises a material in a carrier fluid.

18. The method of claim 12 wherein the sample holder and the strip conductor are located within a chip.

19. The method of claim 12 wherein the detecting the low-volume sample is performed in an inhomogeneous magnetic field.

20. The method of claim 12 wherein the pulse sequence is selected from modified SHARP pulse sequences, zero quantum pulse sequences, and pulsed-spin locking pulse sequences.
